(19) United States
(12) Patent Application Publication
(10) Pub. No.: US 2011/0220177 A1
(43) Pub. Date: Sep. 15, 2011

(54) TANDEM PHOTOVOLTAIC DEVICE WITH DUAL FUNCTION SEMICONDUCTOR LAYER

(75) Inventors: Baojie Yan, Rochester Hills, MI (US); Subhendu Guha, Bloomfield Hills, MI (US); Chi Yang, Troy, MI (US)

(73) Assignee: United Solar Ovonic LLC, Auburn Hills, MI (US)

(21) Appl. No.: 12/721,153

(22) Filed: Mar. 10, 2010

(51) Int. Cl. H01L 31/05; H01B 1/00; H01B 1/04

(52) U.S. Cl. 136/249; 252/500; 252/502

(57) ABSTRACT

A tandem photovoltaic device includes at least two photovoltaic cells stacked in an optical and electrical series relationship. At least one of the tandem cells includes a dual function semiconductor layer fabricated from a dual function semiconductor material. This dual function layer is an electronically active constituent of the cell. The dual function layer also is optically active and creates a reflective condition which redirects a portion of the light which has passed through the cell back through the cell's active layers to photo generate additional photocurrent. Use of the dual function material eliminates the need for incorporating separate semiconductor and reflective layers in a photovoltaic device. Further disclosed are exemplary formulations of some dual function materials.

### STATEMENT OF GOVERNMENT INTEREST

This invention was made with government support under contract DE-FC36-07GO17053 awarded by the Department of Energy. The United States Government has certain rights in the invention.

### FIELD OF THE INVENTION

This invention relates generally to photovoltaic devices. More specifically the invention relates to tandem photovoltaic devices comprised of stacked photovoltaic cells. In particular the invention relates to tandem photovoltaic devices in which one of the electronically active semiconductor layers of at least one of the stacked cells is a dual function layer which also acts as a light-reflective layer.

### BACKGROUND OF THE INVENTION

Tandem photovoltaic devices are constructed to include two or more photovoltaic cells stacked in an optical and electrical series relationship so that incident light passes, serially, through the stacked cells so as to generate a photo current. Since the cells are stacked in an electrical series relationship, the resultant voltage of the photovoltaic device is increased over that which would be obtained with a single cell device. Likewise, stacking the cells in an optical series relationship enhances the absorption of incident light. Furthermore, in many instances, the stacked cells are fabricated from materials having different band gaps and hence different optical absorptions; therefore, such devices (often referred to as spectrum-splitting devices) are capable of utilizing a wider portion of the available spectrum. In constructing tandem photovoltaic devices, it is necessary to maintain proper balance between the photo currents generated by the individual cells so as to optimize the output of the tandem device. Photogenerated current will be proportional to the amount of light absorbed by the cells, and in some instances currents may be balanced by simply controlling the relative thicknesses of the light absorbing layer of the individual cells.

It has previously been appreciated that fabricating the bottom (non-light incident) cell of narrow band gap material, additional photocurrent can be generated. However, the current that is thereby photogenerated in each cell of the tandem must be balanced and, in order to match the current, it is necessary to increase the thickness of the intrinsic layer of the upper (light incident) cell. The problem is that a thicker intrinsic layer is not as effective in collecting photogenerated charge carriers because of light induced degradation known as the “Staebler Wronski” degradation.

The prior art has, in newer generations of tandem photovoltaic devices, utilized light reflective “interlayers” to balance photocurrents. In this approach, a layer of partially light-reflective material is disposed between the stacked cells of the tandem device. This interlayer functions to redirect some portion of the light which has passed through the topmost cell of the stack back through that cell for further absorption. In this manner, photocurrent generated by the top cell is increased, while photocurrent generated by the bottom cell is correspondingly reduced. By utilizing the interlayer, the thickness of the top layer may be decreased thereby realizing economies in the production of these photovoltaic devices and also reducing the light-induced degradation caused by the Staebler-Wronski effect.

In typical prior art implementations, reflective interlayers for tandem photovoltaic devices are prepared from relatively transparent metal oxides such as zinc oxide and the like, as well as nonmetallic oxides such as silicon oxides. Typical layer thicknesses are in the range of 50 to 200 nanometers. U.S. Pat. No. 6,632,993 discloses “hybrid” tandem photovoltaic devices incorporating a light-reflective interlayer that can be fabricated from a variety of materials. The hybrid device is the combination of an amorphous semiconductor top cell and a polycrystalline semiconductor bottom cell having a light incident transparent substrate (glass) and with the interlayer operatively disposed between the two cells.

While there are a number of advantages attendant upon the incorporation of a light-reflective interlayer into a tandem photovoltaic device, the use of a separate interlayer also serves to complicate device manufacture and performance. Further, capital costs increase because extra chambers are required for the vacuum deposition of the interlayer. Incorporation of an additional layer of material into the photovoltaic device will necessitate separate deposition steps and stations thereby complicating process equipment. Additionally, the interlayer can add additional series resistance to the device thereby degrading its overall efficiency of the tandem photovoltaic devices. Also, the quality of the junction between the individual stacked cells in a tandem photovoltaic device is a critical factor in overall device performance (this junction is referred to as a “tunnel junction”) and typically current passes therethrough with very minimal loss. It is important that the junction between the cells not present any significant electronic barrier to current flow; in that regard, it is necessary to establish and maintain a high quality tunnel junction between the cells so as to maximize device efficiency. The presence of a separate interlayer body can interfere with the formation of the tunnel junction.

As will be explained in detail hereinbelow, the present invention has recognized that in tandem photovoltaic devices, certain active semiconductor layers of the component cell can also function as light reflective and redirecting elements thereby securing the advantages of the use of a light-reflective interlayer without requiring the presence of a discrete reflective interlayer. The methods and materials of the present invention enable the maintenance of a high quality tunnel junction between stacked cells while redirecting light back through the device resulting in overall improvement of tandem photovoltaic cell efficiencies. Furthermore, use of the materials and methods of the present invention simplifies the manufacturing of the photovoltaic devices. These and other advantages of the present invention will be apparent from the drawings, discussion, and description which follow. Because no extra layer is needed in the tandem pv structures, the loss in the bottom cell current is not larger than the gain in the top cell current. Therefore, the cell structure in this invention has a significant advantage in terms of total photocurrent in the stacked structure.

### SUMMARY OF THE INVENTION

Disclosed is a tandem photovoltaic device which is comprised of a first and a second photovoltaic triad. Each triad is comprised of a body of substantially intrinsic semiconductor material interposed between a body of p-doped semiconductor material and a body of n-doped semiconductor material. These triads are disposed in a stacked optical and electrical series relationship such that the first triad is closer to the light-incident surface of the photovoltaic device than is the second triad. According to the present invention, the body of n-doped semiconductor material of the first triad is comprised of a dual function, n-doped, hydrogenated, silicon-oxygen material. This dual function semiconductor material is further characterized in that in the operation of the photovoltaic device it establishes a high quality tunnel junction with the p-doped layer of the second triad. In the operation of the photovoltaic device, the dual function layer operates to create a field in the intrinsic body of the first triad which separates photogenerated charge carrier pairs formed therein by absorbed photons. The dual function layer also operates as a partially reflective layer which directs a portion of those photons striking it back into the intrinsic body of the first triad.

In specific instances, the optical band gap of the dual function semiconductor material is in the range of 2.1-2.4 eV. The dual function semiconductor material may be doped with phosphorus, and one specific doping level is in the range of 1-5%. The dual function semiconductor material may, in some instances, also include carbon and nitrogen.

The tandem photovoltaic device may be configured so that the optical band gap of the intrinsic semiconductor material of the first triad is greater than the optical band gap of the second triad. In specific instances, the intrinsic layer of at least one of the triads is comprised of a hydrogenated silicon alloy material, and in other instances at least one of the triads is composed of a hydrogenated silicon-germanium alloy material. In one specific embodiment, the intrinsic layer of the first triad is comprised of a substantially amorphous body of hydrogenated silicon alloy material and the intrinsic body of the second triad is comprised of a nanocrystalline, hydrogenated silicon alloy, or silicon-germanium, material.

Further disclosed is an n-doped hydrogenated silicon-oxygen semiconductor alloy comprising, on an atomic basis: 40-60 at. % of silicon; 60-40 at. % of oxygen; 10-20 at. % of hydrogen; and 10²⁰-10²¹ cm⁻³ of phosphorus. This semiconductor alloy material has an index of refraction in the range of 1.7-2.1, an optical band gap in the range of 2.1-2.4 eV, and an electrical conductivity in the range of 10⁻⁵-10⁻¹ Ω⁻¹cm⁻¹. This semiconductor alloy material may optionally include carbon in and amount of up to 10 atomic percent.

### BRIEF DESCRIPTION OF THE DRAWINGS

FIG. 1 is a cross-sectional view of a generalized tandem photovoltaic device of the prior art;

FIG. 2 is a cross-sectional view of a tandem photovoltaic device of the prior art including a discrete, reflective interlayer; and

FIG. 3 is a cross-sectional view of a tandem photovoltaic device of the present invention incorporating a dual function layer.

### DETAILED DESCRIPTION OF THE PREFERRED EMBODIMENTS

In accord with the present invention, tandem photovoltaic devices are fabricated to include a dual function layer of semiconductor material. This semiconductor layer operates as an active electronic element of the device, and in that regard participates in the generation and/or collection of photogenerated carrier pairs. The layer also functions to reflect light back through the other active layers of the photovoltaic device wherein it is absorbed to generate further carrier pairs. The principles of the present invention will be explained with regard to tandem photovoltaic devices based upon stacked cells, each of which is comprised of a triad of active semiconductor layers. Each triad includes a layer of substantially intrinsic semiconductor material having a layer of p-doped semiconductor material on one side thereof and a layer of n-doped semiconductor material on the other side thereof. It is understood that the central, intrinsic layer of semiconductor material may be slightly p type or slightly n type with regard to its conductivity without compromising the operation of the cell. Therefore, in the context of this disclosure, the central layer is interchangeably referred to as being “intrinsic” or “substantially intrinsic”. It is also to be understood that while the triad is described as including a substantially intrinsic layer of semiconductor material having p-doped and n-doped layers on opposite faces thereof, in many instances the individual layers of the triad may be composites of two or more sublayers. For example, the substantially intrinsic layer may be comprised of a number of sublayers having different or graded band gaps, or other varying physical and/or electronic properties. Likewise, the p-doped layer or the n-doped layer may be comprised of a number of sublayers. In any instance, the principles of the present invention may be implemented in all of such embodiments.

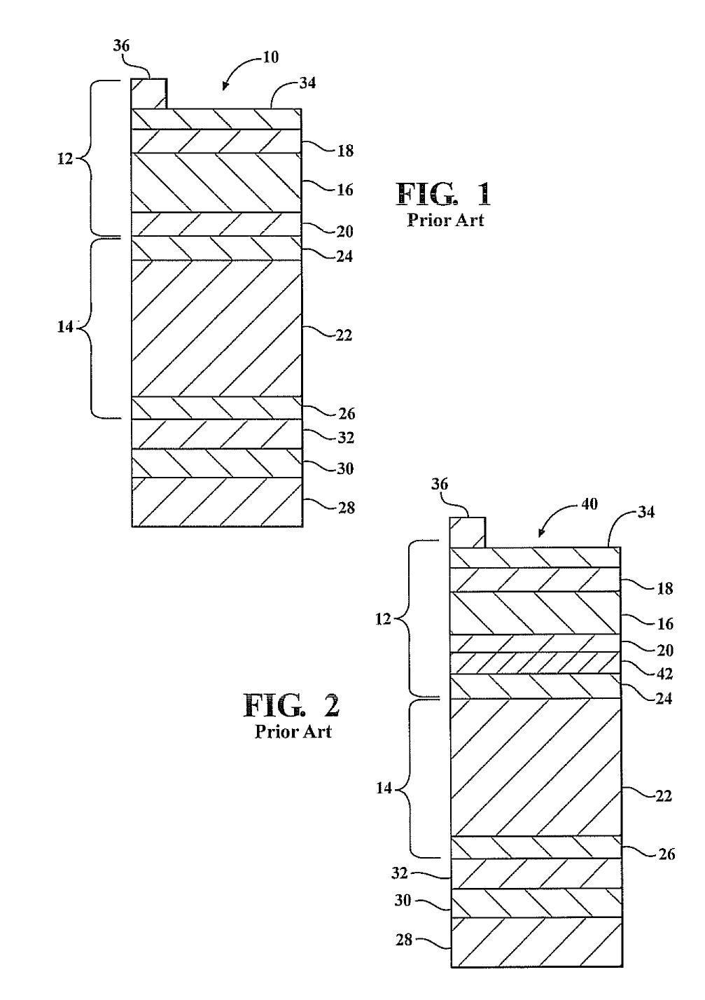

Referring now to FIG. 1, there is shown a simplified cross-sectional view of a generalized tandem photovoltaic device of the prior art, and the present invention will have utility and applicability in devices of this general type, among others. The device 10 of FIG. 1 is a dual tandem photovoltaic device, and in that regard it includes a first photovoltaic cell defined by a first triad 12 of semiconductor layers and a second photovoltaic cell defined by a second triad 14 of semiconductor layers. The first triad 12 is comprised of a body of substantially intrinsic semiconductor material 16 which in this instance is a body of an amorphous silicon-hydrogen alloy material. Disposed on a top face of the intrinsic layer 16 is a layer of p-doped semiconductor material, which in this instance is a layer of nanocrystalline, boron doped silicon-hydrogen alloy material. On the opposite face of the intrinsic layer 16 is a layer of n-doped semiconductor material 20 which in this instance is a layer of phosphorus doped silicon-hydrogen alloy material.

The second triad 14 is comprised of a layer of substantially intrinsic semiconductor material 22, which in this instance is a layer of nano crystalline silicon-hydrogen alloy material. Disposed upon a top surface of the intrinsic layer 22 is a layer of p-doped semiconductor material 24 which is substantially similar to the layer of p-doped semiconductor material 18 in the first triad. On the opposite face of the substantially intrinsic layer 22 is a layer of n-doped semiconductor material 26 which is similar to the layer of n-doped semiconductor material 20 in the first triad.

The device 10 of FIG. 1 is supported upon a stainless steel substrate 28, although in other instances the substrate may be otherwise comprised. For example, the substrate 28 may comprise a body of polymeric material, a body of another metal, a ceramic, glass, or the like. As is known in the art, the substrate 28 forms a bottom electrode of the photovoltaic device, and in those instances where it is fabricated from a material having low electrical conductivity, a layer of metal or the like is supported thereupon to serve as a bottom electrode. In the FIG. 1 embodiment, a back reflector structure is incorporated between the second triad 14 and the substrate 28. This back reflector is comprised of a layer of a reflective metal 30 such as silver, silver alloys, aluminum, aluminum alloys, and the like. Disposed atop the light-reflective 30 is a textured layer of a transparent, electrically conductive material such as zinc oxide. This transparent, textured layer 32 serves to enhance the scattering of reflected light thereby further increasing the efficiency of the device. The photovoltaic device 10 of FIG. 1 includes a top electrode 34 fabricated from a transparent, electrically conductive material such as indium tin oxide, indium oxide, zinc oxide, or some other such transparent, electrically conductive material. A current collecting grid structure 36 is disposed atop the top electrode 34, as is known in the art.

In the operation of the tandem device of FIG. 1, incident light passes through the top electrode 34 and through the p layer 18 of the first triad. This light is partially absorbed by the first substantially intrinsic layer 16. The absorbed light creates electron-hole carrier pairs in the intrinsic layer 16. The electrical field established by the p-doped layer 18 and n-doped layer 20 serves to separate these carrier pairs, and they are ultimately collected by the top electrode 34 and the substrate electrode 28. Unabsorbed light passes through the n-doped layer 20 of the first triad and the p-doped layer 24 of the second triad to the second substantially intrinsic layer 22 where some portion of it is absorbed to create further carrier pairs which are collected as discussed above. Unabsorbed light is reflected back through the triads by the back reflector structure. As described herein the intrinsic layer 16 of the first triad 12 is fabricated from a substantially amorphous silicon-hydrogen alloy, and hence it will have a larger band gap than the second intrinsic body 22 which is fabricated from a nanocrystalline material. In this regard, the first triad will preferentially absorb the shorter wavelengths of the incident spectrum than will the second triad. It is to be understood that while FIG. 1 shows a tandem photovoltaic device comprised of two stacked cells, tandem devices of this type may also be prepared utilizing three or more stacked cells.

Referring now to FIG. 2, there is shown a tandem photovoltaic device 40 of the prior art, incorporating a discrete reflective interlayer therein. The device 40 of FIG. 2 is generally similar to the device 10 of FIG. 1 insofar as it includes two stacked cells comprised respectively of a first triad 12 and a second triad 14. The device 40 of FIG. 2 also includes a substrate 28 and a back reflector structure comprised of a light-reflective layer 30 and a textured transparent conductive layer as well as a top electrode 34 and grid 36, all as previously described. Where FIG. 2 differs from FIG. 1 is that it includes a light-reflective interlayer 42 interposed between the n layer 20 of the first triad 12 and the p layer 24 of the second triad 14. This interlayer 42 operates to reflect some portion of light which has passed through the first triad 12 back therethrough for further absorption. The interlayer 42 is fabricated from a relatively transparent material such as zinc oxide, silicon oxide, or other such oxides. The layer 42 has an index of refraction such that it will establish a reflective condition at its interface with the overlying n-doped layer 20, for at least some of the incident light.

The thickness of the intrinsic layer 16 of the first triad 12 of the device 40 of FIG. 2 is somewhat less than the thickness of the corresponding layer 20 in the FIG. 1 embodiment. This is because the relatively thinner layer of the FIG. 2 embodiment, owing to the presence of the reflective interlayer 42, receives a higher degree of illumination and can generate more current per unit volume than can the thicker layer of the FIG. 1 embodiment.

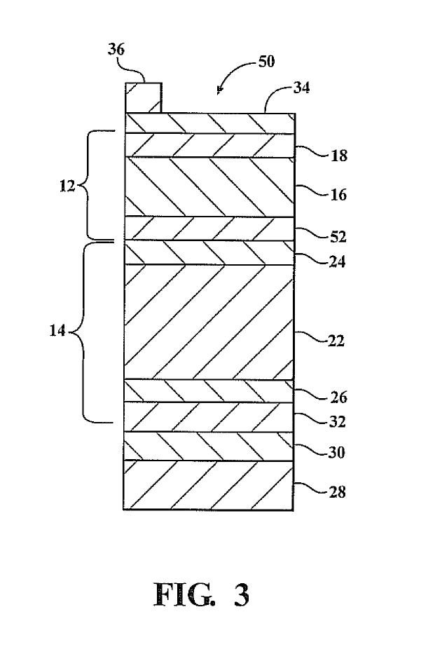

Referring now to FIG. 3, there is shown a tandem photovoltaic device 50 of the present invention. As in the prior drawings, the device 50 of FIG. 3 is comprised of a first triad 12 of semiconductor layers and a second triad 14 of semiconductor layers. The device 50 includes a substrate 28 and back reflector structure comprised of a reflective layer 30 and textured, transparent layer 32 as discussed above. The FIG. 3 device 50 also includes a top electrode 34 and a grid 36 as previously discussed.

Where the FIG. 3 device 50 differs from the FIG. 1 and FIG. 2 devices is with regard to the n-doped layer of the first triad 12. While the first triad 12 of the FIG. 3 device 50 includes a p-doped layer 18 and a substantially intrinsic layer 16 as in the FIG. 1 and FIG. 2 prior art embodiments, the n-doped layer of the first triad in this instance is a dual function layer 52 which operates both as an active, n-doped semiconductor layer and as a reflective layer. In this regard, the layer 52 operates, in combination with the p-doped layer 18, to create a field which separates charge carriers formed in the intrinsic layer 16 and it also operates to reflect light back through the intrinsic layer 16; hence it is referred to as a dual function layer. It will be noted that the substantially intrinsic layer 16 of the FIG. 3 embodiment is generally similar in thickness to the substantially intrinsic layer of the FIG. 2 embodiment, and this is because the dual function layer 52 serves to enhance the illumination passing through it. Thus, the present invention allows for the use of relatively thin bodies of intrinsic material in the top triad, while still preserving practical device efficiency. The thickness limitations of the top triad will depend on the device configuration (dual tandem, triple tandem, etc.) as well as the properties, such as band gap (Eg) of the semiconductor materials comprising the devices (amorphous, nanocrystalline, Si;H, Si;Ge;H, etc). Summarized in Table 1 below are maximum top triad thicknesses for four different tandem device configurations incorporating the dual function layer of the present invention. For each device configuration, the maximum cell thickness is given for instances in which the band gaps of the intrinsic material of the top triad is >1.7 eV and >1.8 eV.

TABLE 1

| | | | Maximum |
|---|---|---|---|
| Device | | Top cell Eg | top triad thickness |
| 1 | a-Si:H/nc-Si:H | >1.8 eV | <300 nm |
| | | >1.7 eV | <250 nm |
| 2 | a-Si:H/a-SiGe:H | >1.8 eV | <220 nm |
| | | >1.7 eV | <180 nm |
| 3 | a-Si:H/nc-Si:H/nc-Si:H | >1.8 eV | <250 nm |
| | | >1.7 eV | <200 nm |
| 4 | a-Si:H/a-SiGe:H/a-SiGe:H | >1.8 eV | <150 nm |
| | | >1.7 eV | <120 nm |

One further advantage of the present invention will be apparent from a comparison of the prior art device 40 of FIG. 2 with the inventive device 50 of FIG. 3. In the prior art device, reflection of light takes place at the interface of the interlayer 42 with the n layer 20 of the first triad 12. Hence, the reflected light must pass through the n layer 20 before it reaches the intrinsic layer 16. Some portion of this reflected light will be absorbed, non-productively, in the n layer 20 and not be available for the generation of carrier pairs. In the device 50 of the present invention, light is reflected at the interface of the dual function layer 52 and the substantially intrinsic layer 16; therefore all of the reflected light is available for the generation of carrier pairs in the intrinsic layer 16.

As discussed above, the efficient operation of a tandem photovoltaic device requires that charge carriers passing between the interface of a first triad and a second triad not encounter any significant barriers which would impede their flow and thereby degrade the efficiency of the device. In this regard it is essential that a high quality tunnel junction be established between the triads. It is notable that use of the dual function layer of the present invention allows for the maintenance of a high quality tunnel junction between the triads. The dual function layer of the present invention should, in addition to fostering the creation of a high quality tunnel junction, have an index of refraction such that it will create reflective conditions at its interface with the superjacent body of substantially intrinsic semiconductor material. In this regard, the index of refraction will typically be in the range of 1.7-2.1 The dual function semiconductor material should also have reasonably good electrical conductivity, and in specific instances it will have a conductivity in the range of 10⁻⁵-10⁻¹ Ω⁻¹cm⁻¹. Optical band gap properties of the material of this layer should be compatible with the photovoltaic device and typically will fall in the range of 2.1-2.4 eV.

Since the dual function layer reflects light back through the intrinsic layer of its triad, it will establish an interference condition which will be correlatable with the thickness of the intrinsic layer. This interference condition will be evidence of the presence of the reflective function of the layer. And in this regard, the quantum efficiency curve of the device, which is understood in the art to be a plot of the quantum efficiency versus illuminating wavelength, will manifest interference fringes, which can be correlated with intrinsic layer thickness.

One group of semiconductor materials having utility as dual function layer materials in the present invention comprise semiconductors based upon hydrogenated silicon-oxygen alloys. These materials may be doped to have n-type conductivity by the use of dopants such as phosphorus. A specific group of materials of this type comprise, on an atomic basis, 40-60% silicon; 40-60% oxygen; 10-20% hydrogen, with phosphorus doping levels being in the range of 0.5-5%. These materials may optionally include carbon in an amount of up to 10%. One specific group of materials used in the present invention comprised approximately 60-70% silicon, 30-40% oxygen, 10-20% hydrogen, and approximately 1-3% of carbon.

In general, the dual-function semiconductor layers can be deposited using various methods, such as plasma enhanced chemical vapor deposition (PECVD), hot-wire chemical vapor deposition (Hot-wire-CVD), and photo-induced chemical vapor deposition (Photo-CVD). For PECVD, the excitation sources can be DC power, radio frequency (rf), very high frequency (vhf), and microwave. The deposition temperature should be compatible with the process parameters in other layers in the tandem solar cell structures. Normally, it covers the range from 100° C. to 350° C. The deposition pressure depends on the methods used in the process; it ranges from milli-torrs to atmospheric pressure. The process gases include silicon containing gases such as SiH₄, Si₂H₆, and Si₃H₈; gases containing oxygen, carbon, and nitrogen such as CO, CO₂, CH₄, C₂H₄, C₂H₆, NO₂; diluent gases such as H₂, Ar, and He; and dopant gases such as PH₃, BF₃, B₂H₆, and B(CH₃)₃.

Examples which demonstrate the concept of the present invention are given below. The dual-function layer is, in one embodiment, a SiOx:H film deposited using a vhf PECVD method with a hydrogen diluted Si₂H₆ and CO₂ mixture, where PH₃ is used as n-doping gas. The n-doped SiOx:H layer contains nanocrystallites disposed in an amorphous matrix such that the current can pass through the low resistance nanocrystalline paths. In addition, the level of phosphorus doping is relatively high and moves the Fermi level of the material toward the conduction band edge, which makes this material suitable for the n layer of a-Si:H top cell. The refractive index of the material can be tuned in a range of 1.7 to 3.6 by changing the ratio of CO₂/Si₂H₆. The specific material used in the a-Si:H/nc-Si:H tandem solar cells contains about 50 at. % of Si, 44 at. % O, and 6 at. % of C. The optical band gap is 2.3 eV, refractive index is 2.0, and the vertical conductivity is high enough to form good a tunnel junction. Because the n-doped SiOx:H is used as the top cell n layer, it has wider band gap and lower absorption coefficients than conventional n-doped a-Si:H and nc-Si:H, the light absorption in the tunnel junction with the dual function SiOx:H n layer is reduced significantly.

As reported in the prior art, the interlayer in discrete interlayer tandem solar cells causes a loss in the bottom cell current, which is larger than the gain in the top cell current because the interlayer induces extra light absorption and it also reflects some long wavelength light that cannot be absorbed by the top cell. In the present invention, the dual function SiOx:H layer replaces the n layer in the top cell; thus, the absorption is reduced comparing to the cell structure with no interlayer as shown in FIG. 1. Although there could be some reflected long wavelength light that could not be absorbed by the top cell, the overall loss in the bottom cell current is not more than the gain in the top cell current.

In an experimental series, the performance of a tandem photovoltaic cell of the present invention was compared with that of prior art cells of the type shown in FIGS. 1 and 2. The first prior art device of this series, referred to herein as device A, comprises two stacked triads having no interlayer therebetween. The topmost triad of device A included a substantially intrinsic layer fabricated from an amorphous, hydrogenated, silicon alloy material. The intrinsic layer of the bottom triad was fabricated from a narrower band gap hydrogenated nanocrystalline silicon alloy material. The second device, referred to herein as device B, was generally similar to device A except that it included an interlayer fabricated from a SiOx:H material inserted between the pin tunnel junction. The third device, C, was structured in accord with the present invention. In that regard it included stacked triads generally similar to those of cells A and B, except that the n doped layer of the top triad was a dual function layer in accord with the present invention and comprised a phosphorus doped hydrogenated silicon oxygen material.

The three devices were evaluated in accord with art-recognized procedures. In that regard, quantum efficiency, as a function of illuminating wavelength, was measured for each of the constituent triads of each of the three devices utilizing an AM 1.5 solar spectrum. Current densities for the constituent triads and total current densities for the devices were obtained from the integrals of the quantum efficiency/wavelength curves, and these results are summarized in Table 2 below.

TABLE 2

| | | Current density (mA/cm²) | | |
|---|---|---|---|---|
| Device | Structure | Top | Bottom | Total |
| A | No interlayer | 11.16 | 11.23 | 22.39 |
| B | With interlayer | 11.66 | 9.18 | 20.84 |
| C | With SiOx:H n layer in top cell | 11.66 | 11.45 | 23.11 |

The results of this experimental series demonstrated that in device B the presence of the interlayer increases the current density in the top triad from 11.16 to 11.66 mA/cm², but decreases the current density of the bottom triad from 11.23 to 9.18 mA/cm². This observed result is similar to published results found in the literature.

In device C, the dual function layer increased the current density of the top triad to 11.66 mA/cm², and also increased the current density of the bottom triad to 11.45 mA/cm². As will be seen from Table 1, the performance of device C with regard to overall current density as well as current density of the triads exceeded that of the prior art devices A and B.

It is known in the art that exposure to illumination can cause a degradation in the efficiency of operation of photovoltaic devices, and the extent of such degradation is dependent upon specific materials and device configuration. In a further experimental series, the effect of photo-induced degradation on the aforedescribed tandem devices of the prior art and present invention was evaluated. In this regard, devices A, B and C as described above were evaluated with regard to performance characteristics including fill factor, maximum power, short circuit current, and efficiency. Thereafter, the devices were light soaked for a period of 800 hours under AM 1.5 illumination, and their properties were measured once again. Results of this evaluation are summarized in Table 3 below.

TABLE 3

| Sample | | Voc | | Jsc | Eff | Rs | |
|---|---|---|---|---|---|---|---|
| # | State | (V) | FF | (mA/cm²) | (%) | (Ω · cm²) | Comment |
| A | Initial | 1.453 | 0.690 | 11.16 | 11.19 | 13.5 | Baseline |
| | Stable | 1.444 | 0.644 | 10.75 | 10.00 | 17.2 | with no inter-layer |
| | Change | −0.7% | −6.6% | −3.7% | −10.7% | 27.6% | |
| B | Initial | 1.432 | 0.740 | 9.18 | 9.73 | 13.1 | With SiOx:H |
| | Stable | 1.438 | 0.720 | 9.11 | 9.44 | 14.8 | interlayer |
| | Change | 0.4% | −2.7% | −0.8% | −3.0% | 13.0% | |
| C | Initial | 1.416 | 0.668 | 11.66 | 11.03 | 15.5 | With SiOx:H |
| | Stable | 1.429 | 0.640 | 11.25 | 10.29 | 16.4 | n layer |
| | Change | 0.9% | −4.1% | −3.5% | −6.7% | 5.8% | in top cell |

As discussed above, both the discrete interlayer of the prior art and the dual function layer of the present invention operate to redistribute current densities between the top and bottom triads; however, the gain in top cell current and reduction in bottom cell current by the discrete interlayer of cell B leads to a very large current mismatch in the device. While this mismatch is detrimental to overall device operation, it does produce an apparently improved fill factor as compared to the other devices. As will be seen from the data, light soaking degrades the efficiency by 10.7% for the baseline cell and degrades the efficiency of the discrete interlayer cell by 3.0%, which is again attributable to the large current mismatch. Similar light soaking produces 6.7% degradation in the efficiency of the device of the present invention. It will also be seen that the open circuit voltage is slightly increased in all devices by light soaking. Combining all the characteristics, the stable efficiency of the device of the present invention is found to be 3% higher than that of the baseline cell.

As discussed above, the current produced by the top triad in a tandem device may be increased, in the absence of any reflective interlayer, by simply increasing the thickness of the intrinsic layer of that triad. However, doing so increases deposition time, material cost, and size of the deposition system. And, even more significantly, thicker layers are more prone to photo degradation, which compromises device performance. In a further experimental series, the performance of tandem devices of the present invention were compared with the performance of generally similar tandem devices which did not include an interlayer but did include thicker top cell triads. In this experimental series, as summarized in Table 3 below, a series of four devices were compared. Device A is generally similar to the device A discussed above and comprised a tandem stack of two triads which did not include any interlayer. Device B is generally similar to device A, except that the intrinsic layer of the top triad was 20% thicker than that of device A. Device C was generally similar to device A except that the intrinsic layer of the top triad was 44% thicker than that of device A. Device D was the device of the present invention as described above. For each of these devices, the current density was measured in accord with the techniques described with regard to Table 2.

TABLE 4

| | | Current density | | |
|---|---|---|---|---|
| | | (mA/cm²) | | |
| Device | Structure | Top | Bottom | Total |
| A | No interlayer | 10.99 | 13.84 | 25.04 |
| B | No interlayer, but 20% thicker top cell | 11.43 | 13.46 | 24.87 |
| C | No interlayer, but 44% thicker top cell | 11.66 | 12.36 | 24.02 |
| D | With SiOx:H n layer in top cell | 11.85 | 12.62 | 24.47 |

As will be seen from Table 4, increasing top cell thickness can increase the top cell current, but the effect is not as strong as expected. Increasing top cell thickness by 44% as shown in device D results in a current gain of 0.67 mA/cm². However, use of the dual function SiOx:H layer of the present invention leads to an increased top cell current of 0.86 mA/cm². In addition to being uneconomical to prepare, devices having increased thicknesses in the intrinsic layers of the upper cell suffer from increased photo degradation as compared to the inner cells of the present invention. In a further experimental evaluation, the four devices of Table 4 were subjected to light-induced degradation by light soaking for 500 hours. As described with regard to Table 3, the performance characteristics of devices A-D were evaluated before and after the light soaking. The results of these evaluations are summarized in Table 5 hereinbelow.

TABLE 5

| Sample | | Voc | | Jsc(top) | Eff | Rs | |
|---|---|---|---|---|---|---|---|
| # | State | (V) | FF | (mA/cm²) | (%) | (Ω · cm²) | Comment |
| A | Initial | 1.403 | 0.686 | 10.99 | 10.58 | 14.88 | Baseline |
| | Stable | 1.374 | 0.635 | 10.62 | 9.26 | 16.92 | |
| | Change | −2.1% | −7.5% | −3.4% | −12.5% | 13.7% | |
| B | Initial | 1.392 | 0.662 | 11.43 | 10.52 | 16.85 | Baseline with |
| | Stable | 1.359 | 0.602 | 11.01 | 9.01 | 18.10 | 20% thicker |
| | Change | −2.4% | −9.0% | −3.7% | −14.4% | 7.4% | top cell |
| C | Initial | 1.412 | 0.658 | 11.66 | 10.84 | 14.43 | Baseline with |
| | Stable | 1.368 | 0.595 | 11.23 | 9.14 | 18.10 | 44% thicker |
| | Change | −3.1% | −9.6% | −3.7% | −15.6% | 25.5% | top cell |
| D | Initial | 1.392 | 0.638 | 11.85 | 10.52 | 16.93 | With dual-function |
| | Stable | 1.374 | 0.611 | 11.54 | 9.69 | 16.80 | SiOx:H n layer |
| | Change | −1.3% | −4.1% | −2.6% | −7.8% | −0.7% | in top cell |

As will be seen from this data, increasing the top cell thickness results in extra light-induced degradation as compared to the baseline device A. In contrast, the use of the dual function layer of the present invention, as shown in device D, increases top cell current as effectively as does thickening the top cell, without increasing the amount of light-induced degradation. In fact, the overall light-induced degradation in device D is lower than that of any of the other devices.

In summary, the foregoing demonstrates that use of a dual function layer in the top cell of tandem photovoltaic devices will effectively increase the top cell current at least as effectively as does a discrete interlayer without decreasing bottom cell current so that the loss in bottom cell current is not larger than the gain in top cell current. This preserves current balance and increases device efficiency. Furthermore, light soaking experiments show that the tandem cell of the present invention with a dual function layer has lower light-induced degradation than do tandem cells with thicker top cell intrinsic layers. Overall, the dual function layer of the present invention operates to increase stable tandem cell efficiency.

In a further experimental series, performance characteristics of four different types of tandem photovoltaic device structured in accord with the principles of the present invention were investigated. Device 1 was a dual tandem photovoltaic device having a top triad which contained an intrinsic layer fabricated from an amorphous silicon hydrogen alloy. The device included a second triad which had an intrinsic layer fabricated from a narrower band gap amorphous silicon germanium hydrogen alloy material. Device 2 was a triple tandem photovoltaic device comprised of three stacked triads. The intrinsic layer of the first triad was comprised of an amorphous silicon hydrogen alloy; the intrinsic layer of the second triad was fabricated from an amorphous silicon germanium hydrogen alloy; and the intrinsic layer of the third triad was fabricated from an amorphous silicon germanium hydrogen alloy. A third device was a dual tandem device having a first triad with an intrinsic layer fabricated from an amorphous silicon hydrogen alloy and a second triad with an intrinsic layer fabricated from a nanocrystalline silicon hydrogen alloy. A fourth device was a triple tandem device having a first triad in which the intrinsic layer was fabricated from an amorphous silicon hydrogen alloy; the intrinsic layer of the second triad was fabricated from a nanocrystalline silicon hydrogen alloy; and the third triad had an intrinsic layer fabricated from a nanocrystalline silicon hydrogen alloy material. In each of the devices, the n-doped layer of the top triad was a dual function layer in accord with the present invention. Performance characteristics of these devices were measured with regard to short circuit current (Jsc), open circuit voltage (Voc), and fill factor (FF). The efficiency of each of the devices was calculated from the foregoing parameters. In addition, a target efficiency was determined for each of the devices based upon expected efficiency from an optimized device. Table 6 below summarizes the results of this experimental series.

TABLE 6

| | | Jsc | Voc | | Eff |
|---|---|---|---|---|---|
| | Device Structure | mA/cm² | volts | FF | (%) |
| 1 | a Si:H/ | 9.50 | 1.65 | 0.64 | 10.03 |
| | a SiGe:H | | | | |
| 2 | a Si:H/ | 7.00 | 2.25 | 0.67 | 10.55 |
| | a SiGe:H/ | | | | |
| | a SiGe:H | | | | |
| 3 | a Si:H/ | 12.00 | 1.43 | 0.67 | 11.50 |
| | nc SiH | | | | |
| 4 | a Si:H/ | 8.80 | 1.95 | 0.70 | 12.01 |
| | nc Si:H/ | | | | |
| | nc Si:H | | | | |

It will be seen from the foregoing that devices which incorporate the dual function layer of the present invention all show efficiencies which equal or surpass a target value for optimized devices. This high level of performance is characteristic of devices of the present invention, and values for the short circuit voltage, open circuit voltage, and fill factor as determined herein are indicative of use of the present invention in the described devices.

It will be seen from the foregoing that use of the dual function semiconductor layer of the present invention in tandem photovoltaic devices represents a significant improvement over the prior art insofar as it recognizes that particular semiconductor material can be advantageously employed in a dual function role which allows for the elimination of discrete interlayer structures. The dual function material provides a layer having both very good electronic properties with regard to creation and maintenance of an internal field and fostering of a high quality tunnel junction as well as good optical properties which allow for the creation of reflective interface conditions. This result is surprising and unexpected given that the prior art has heretofore employed separate electronic and optical layers and has not believed that an optical material having good transparency and a relatively high index of refraction could also function as an effective field-forming, tunnel junction promoting, doped semiconductor material. Use of the present invention greatly simplifies the construction and manufacture of high efficiency photovoltaic devices.

While the foregoing discussion and description was directed to tandem photovoltaic devices comprising stacked triads of p-i-n construction, it is to be understood that the principles hereof may be extended to tandem devices comprised of other structures such as p-n structures and the like. Also, it is to be understood that the present invention may be readily implemented by one of skill in the art with regard to devices including three or more stacked photovoltaic cells. In such instance, the dual function layer of the present invention may be incorporated in one or more of the individual cells as appropriate.

In view of the teaching presented herein, numerous other modifications and variations of the invention will be apparent to those of skill in the art. The foregoing drawings, discussion, and description are illustrative of specific embodiments but are not meant to be limitations upon the practice of the present invention. It is the following claims, including all equivalents, which define the scope of the invention.

1. A tandem photovoltaic device comprised of a first and a second photovoltaic triad, each triad comprising a body of a substantially intrinsic semiconductor material interposed between a body of p-doped semiconductor material and a body of n-doped semiconductor material, said triads being disposed in a stacked, optical and electrical series relationship such that said first triad is closer to the light-incident side of said photovoltaic device than is said second triad, wherein the body of n-doped semiconductor material of said first triad is a dual function semiconductor material comprised of an n-doped, hydrogenated, silicon-oxygen material;
whereby in the operation of said tandem photovoltaic device, said dual function layer operates (i) to create a field in the intrinsic body of the first triad, which field separates photogenerated charge carrier pairs formed in said intrinsic semiconductor material by absorbed photons, and (ii) as a partially reflective layer which redirects a portion of those photons of the incident solar spectrum striking it back to the intrinsic body of the first triad.

2. The photovoltaic device of claim 1, wherein said device is a dual tandem device in which the intrinsic body of the first triad is comprised of an amorphous silicon:hydrogen semiconductor material and the intrinsic body of the second triad is comprised of an amorphous silicon:germanium:hydrogen semiconductor material, and wherein said device has a stable, short circuit current of at least 9.50 mA/cm².

3. The photovoltaic device of claim 2, wherein said device has a fill factor of at least 0.64.

4. The photovoltaic device of claim 2, wherein said device has an open circuit voltage of at least 1.65V.

5. The photovoltaic device of claim 1, wherein said device is a dual tandem device in which the intrinsic body of the first triad is comprised of an amorphous silicon:hydrogen semiconductor material and the intrinsic body of the second triad is comprised of a nanocrystalline silicon:hydrogen semiconductor material, and wherein said device has a stable, short circuit current of at least 12.00 mA/cm².

6. The photovoltaic device of claim 5, wherein said device has a fill factor of at least 0.67.

7. The photovoltaic device of claim 5, wherein said device has an open circuit voltage of at least 1.43V.

8. The photovoltaic device of claim 1, wherein said device is a triple tandem device further including a third photovoltaic triad stacked in an optical and electrical relationship with the first and second triad, so that the second triad is interposed between said first and third triad, wherein the intrinsic body of the first triad is comprised of an amorphous silicon:hydrogen semiconductor material, the intrinsic body of the second triad is comprised of an amorphous silicon:germanium:hydrogen semiconductor material, the intrinsic body of the third triad is comprised of an amorphous silicon:germanium:hydrogen semiconductor material, and wherein said device has a stable, short circuit current of at least 7.00 mA/cm².

9. The photovoltaic device of claim 8, wherein said device has a fill factor of at least 0.67.

10. The photovoltaic device of claim 8, wherein said device has an open circuit voltage of at least 2.25V.

11. The photovoltaic device of claim 1, wherein said device is a triple tandem device further including a third photovoltaic triad stacked in an optical and electrical relationship with the first and second triad, so that the second triad is interposed between said first and third triad, wherein the intrinsic body of the first triad is comprised of an amorphous silicon:hydrogen semiconductor material, the intrinsic body of the second triad is comprised of a nanocrystalline silicon:hydrogen semiconductor material, the intrinsic body of the third triad is comprised of nanocrystalline silicon:hydrogen semiconductor material, and wherein said device has a stable, short circuit current of at least 8.80 mA/cm².

12. The photovoltaic device of claim 11, wherein said device has a fill factor of at least 0.70.

13. The photovoltaic device of claim 11, wherein said device has an open circuit voltage of at least 1.95V.

14. The photovoltaic device of claim 1, wherein said dual function semiconductor material includes 1-5% of a phosphorus dopant.

15. The photovoltaic device of claim 1, wherein said dual function semiconductor material further includes carbon and/or nitrogen.

16. The photovoltaic device of claim 1, wherein the optical band gap of the substantially intrinsic semiconductor material of said first triad is greater than is the optical band gap of the substantially intrinsic semiconductor material of said second triad.

17. The photovoltaic device of claim 1, wherein the substantially intrinsic layer of at least one of said triads is comprised of a hydrogenated silicon alloy material.

18. The photovoltaic device of claim 1, wherein the substantially intrinsic layer of at least one of said triads is selected from the group comprised of (i) hydrogenated silicon-germanium alloy material, or (ii) nanocrystalline silicon hydrogen alloy material.

19. The photovoltaic device of claim 1, wherein said n-doped, hydrogenated, silicon-oxygen semiconductor alloy comprises, on an atomic basis:
40-60% silicon;
40-60% oxygen;
10-20% hydrogen; and
0.1-1.5% phosphorus.

20. The photovoltaic device of claim 1, including the dual function layer and wherein the thickness of the intrinsic layer of the top cell is no thicker than a similar photovoltaic device without the inclusion of the dual function layer.

21. The photovoltaic device of claim 1 including the dual function layer and wherein the total current photogenerated in the top and bottom cells is greater than the current photogenerated in the absence of that dual function layer.

22. The photovoltaic device of claim 1, further characterized in that the quantum efficiency curve of the device shows an interference fringe which is correlatable with the thickness of the intrinsic body of the top triad.

23. The photovoltaic device of claim 1, wherein:
A. when said device is a dual tandem device in which the intrinsic body of the first triad is comprised of an amorphous silicon:hydrogen semiconductor material and the intrinsic body of the second triad is comprised of a nanocrystalline hydrogen semiconductor material, said device being characterized in that when the band gap of the intrinsic body of the first triad is greater than 1.8 eV, the maximum thickness of said first triad is less than 300 nm, and when the band gap of the intrinsic body of the first triad is greater than 1.7 eV, the maximum thickness of said first triad is less than 250 nm;
B. when said device is a dual tandem device in which the intrinsic body of the first triad is comprised of an amorphous silicon:hydrogen semiconductor material and the intrinsic body of the second triad is comprised of an amorphous silicon: germanium:hydrogen semiconductor material, said device being characterized in that when the band gap of the intrinsic body of the first triad is greater than 1.8 eV, the maximum thickness of said first triad is less than 220 nm, and when the band gap of the intrinsic body of the first triad is greater than 1.7 eV, the maximum thickness of said first triad is less than 180 nm;
C. when said device is a triple tandem device further including a third photovoltaic triad stacked in an optical and electrical relationship with the first and second triad, so that the second triad is interposed between said first and third triad, wherein the intrinsic body of the first triad is comprised of an amorphous silicon:hydrogen semiconductor material, the intrinsic body of the second triad is comprised of a nanocrystalline silicon:hydrogen semiconductor material, the intrinsic body of the third triad is comprised of nanocrystalline silicon:hydrogen semiconductor material, said device being characterized in that when the band gap of the intrinsic body of the first triad is greater than 1.8 eV, the maximum thickness of said first triad is less than 250 nm, and when the band gap of the intrinsic body of the first triad is greater than 1.7 eV, the maximum thickness of said first triad is less than 200 nm; and
D. when said device is a triple tandem device further including a third photovoltaic triad stacked in an optical and electrical relationship with the first and second triad, so that the second triad is interposed between said first and third triad, wherein the intrinsic body of the first triad is comprised of an amorphous silicon:hydrogen semiconductor material, the intrinsic body of the second triad is comprised of an amorphous silicon:germanium:hydrogen semiconductor material, the intrinsic body of the third triad is comprised of an amorphous silicon:germanium:hydrogen semiconductor material, said device being characterized in that when the band gap of the intrinsic body of the first triad is greater than 1.8 eV, the maximum thickness of said first triad is less than 150 nm, and when the band gap of the intrinsic body of the first triad is greater than 1.7 eV, the maximum thickness of said first triad is less than 120 nm.

24. An n-doped, hydrogenated, silicon-oxygen semiconductor alloy comprising, on an atomic basis:
40-60% silicon;
40-60% oxygen;
10-20% hydrogen; and
0.1-1.5% phosphorus;
said semiconductor alloy having an index of refraction in the range of 1.7-2.1, an optical band gap in the range of 2.1-2.4 eV, and an electrical conductivity in the range of 10⁻⁵-10⁻¹ Ω⁻¹cm⁻¹.

25. The semiconductor alloy of claim 24, further comprising, on an atomic basis, a material selected from the group consisting of: carbon and/or nitrogen.
